(19) United States
(12) Patent Application Publication
(10) Pub. No.: US 2007/0269967 A1
(43) Pub. Date: Nov. 22, 2007

(54) Manufacturing method of semiconductor device

(75) Inventor: Hiroaki Taketani, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Elpida Memory, Inc., Tokyo (JP)

(21) Appl. No.: 11/802,176

(22) Filed: May 21, 2007

(30) Foreign Application Priority Data
May 22, 2006 (JP) 2006-141894

(51) Int. Cl. H01L 21/265

(52) U.S. Cl. 438/519

(57) ABSTRACT

A method for manufacturing a semiconductor device is provided, which is capable of solving a junction leakage problem. According to the manufacturing method of the present invention, arsenic is implanted to reduce the series resistance after formation of a contact hole. A sidewall film is then formed on the side surface defining the contact hole. Silicon is etched by using the sidewall film as a mask to thereby remove the region containing many implantation damages around the projected range position of arsenic while leaving unetched the arsenic region directly below the sidewall film. The removal of the secondary defect region having many implantation damages is effective to prevent occurrence of junction leak current.

This application claims priority to prior Japanese application JP 2006-141894, the disclosure of which is incorporated herein by reference.

### BACKGROUND OF THE INVENTION

The present invention relates to a manufacturing method of a semiconductor device and, in particular, to a manufacturing method of a semiconductor device which causes less junction leak current.

Element patterns have been made finer and finer along with the increase of the integration density of semiconductor devices. For example, dynamic random access memories (hereafter, referred to as “DRAMs”) with a capacity of 1 GB have been commercialized and put to practical use. Manufacturing methods of these large-capacity DRAMs have been improved in various manners to cope with the refinement of element dimensions.

In one of these improved manufacturing methods, ions having a short projected range position are implanted after formation of a contact hole to reduce the contact resistance in a source/drain portion. The implantation of the ions with a short projected range position, that is, heavy ions increases the possibility of occurrence of defects and/or lattice distortions around the projected range position of the ions. Accordingly, defect recovery is performed by heat treatment after the ion implantation. In order to realize a high integration density, however, the junction in the source/drain portion must be kept shallow. Therefore, the heat treatment cannot be performed sufficiently after the ion implantation. If the heat treatment is insufficient, secondary defects will be left around the projected range position.

On the other hand, during operation of the semiconductor device, a depletion layer is produced in the source/drain portion by applied voltage. Since the junction is shallow, the depletion layer extending from the drain junction to the direction of the contact hole of the drain will come into contact with the aforementioned secondary defects, leading to generation of junction leak current. When the junction leakage occurs, electric charge will leak from a memory cell capacitor of the DRAM, leading to deterioration in the refresh characteristics. According to the conventional technique, as described above, the ion implantation performed to decrease the contact resistance allows lattice distortions and defects to remain around the projected range position, and the defects come into contact with the depletion layer, causing occurrence of junction leakage. The junction leakage will induce a problem of deterioration in the refresh characteristics of the DRAM.

Such defects caused by ion implantation are described in several patent publications. For example, in Japanese Laid-Open Patent Publication No. H11-67682, rare-gas ions are implanted into a diffusion layer and heat treated to generate voids for gettering of defects. According to Japanese Laid-Open Patent Publication No. H11-121573, a diffusion layer is selectively etched after removal of defects due to ion implantation, so that a carrier concentration profile and junction are evaluated. These patent publications, however, do not give any description or technical implication about the manufacturing method of the present invention.

### SUMMARY OF THE INVENTION

As described above, when a junction is shallow, lattice distortions and/or defects will be left around the projected range position of ion implantation that is performed to reduce the contact resistance. The contact between the defects and a depletion layer will induce a problem of junction leakage. In view of the problems, it is an object of the present invention to provide a method for manufacturing a semiconductor device generating little junction leak current.

In order to achieve the object above, the present invention basically employs the techniques as described below. It should be understood that other applied techniques that can be variously modified without departing from the scope of the present invention are also covered by the present invention.

The present invention provides a manufacturing method for semiconductor device which includes an ion implantation step of performing ion implantation to form a resistance reduction diffusion layer; and an etching step of etching away a damaged region of the resistance reduction diffusion layer formed by the ion implantation.

In the method for manufacturing a semiconductor device according to the present invention, a sidewall film is formed after the ion implantation step, and the damaged region of the resistance reduction diffusion layer formed by the ion implantation is etched away by using the sidewall film as a mask.

In the method for manufacturing a semiconductor device according to the present invention, an electric field relaxation diffusion layer is further formed by using the mask after the etching step.

In the method for manufacturing a semiconductor device according to the present invention, the sidewall film includes a nitride film.

In the method for manufacturing a semiconductor device according to the present invention, the sidewall film includes a silicon oxide film.

In the method for manufacturing a semiconductor device according to the present invention, the damaged region is removed by being etched away to a depth of approximately 10 nm by the etching step.

In the method for manufacturing a semiconductor device according to the present invention, the resistance reduction diffusion layer is formed by implantation of arsenic ions.

A method for manufacturing a semiconductor device according to the present invention includes the steps of: forming a side oxide film; forming a low concentration diffusion layer by using the side oxide film as a first mask; forming a first sidewall film on the side oxide film; forming a resistance reduction diffusion layer by using the first sidewall as a second mask; forming a second sidewall film on the first sidewall; etching away a damaged region of the resistance reduction diffusion layer by using the second sidewall as a third mask; and forming an electric field relaxation diffusion layer by using the third mask.

The present invention also provides semiconductor device which is includes a resistance reduction diffusion layer formed by ion implantation. A damaged region of the resistance reduction diffusion layer formed by the ion plantation is etched away.

In the semiconductor device according to the present invention, the semiconductor device is a dynamic random access memory.

According to the method for manufacturing a semiconductor device of the present invention, arsenic ion implantation is performed after formation of a contact hole for reducing the series resistance, and then a sidewall film is formed on a side surface defining the contact hole. Silicon is etched away by using the sidewall film as a mask to thereby remove the region containing many implantation damages around the projected range position of arsenic while leaving unetched the arsenic region directly below the sidewall film. The removal of the secondary defect region having many implantation damages is effective to suppress the remaining of secondary defects and to prevent occurrence of junction leak current. When the present invention is applied to a DRAM cell transistor, the probability of remaining of implantation defects can be reduced. The DRAM refresh time is improved and the refresh defective rate is reduced. As a result, the method for manufacturing a semiconductor device of the present invention has high reliability and high manufacture yield.

### BRIEF DESCRIPTION OF THE DRAWINGS

FIGS. 1A and 1B are cross-sectional views showing the vicinity of a drain according to a first embodiment and a related art, respectively;

FIG. 2 is a diagram illustrating gate voltage dependency of drain current;

FIGS. 3A, to 3L are cross-sectional views showing primary steps according to a first embodiment of the present invention;

FIGS. 4E to 4J are cross-sectional views showing primary steps according to a second embodiment of the present invention; and

FIG. 5 is a diagram illustrating correlation between refresh time and rejection rate.

### DESCRIPTION OF THE PREFERRED EMBODIMENTS

A method for manufacturing a semiconductor device according to the present invention will be described with reference to the accompanying drawings.

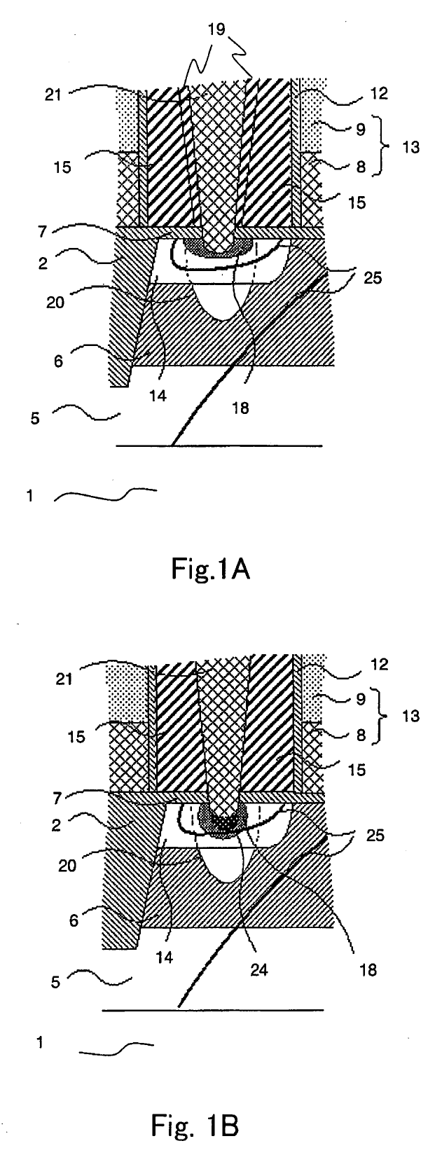

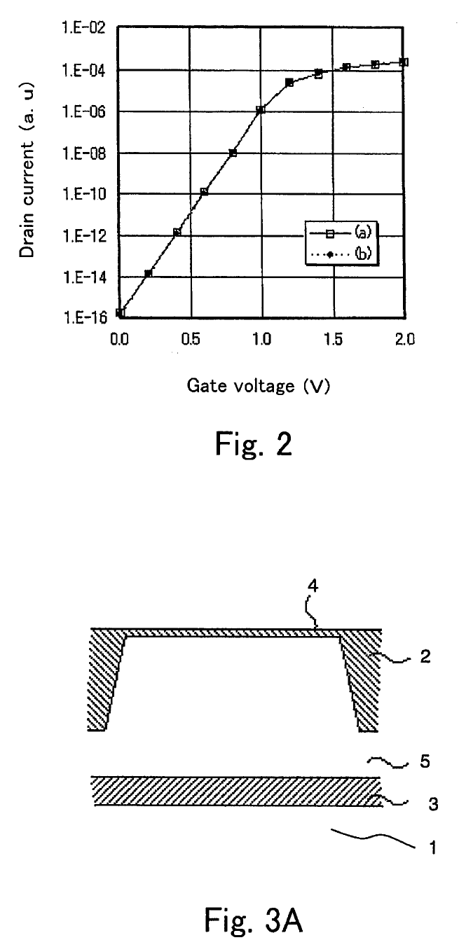

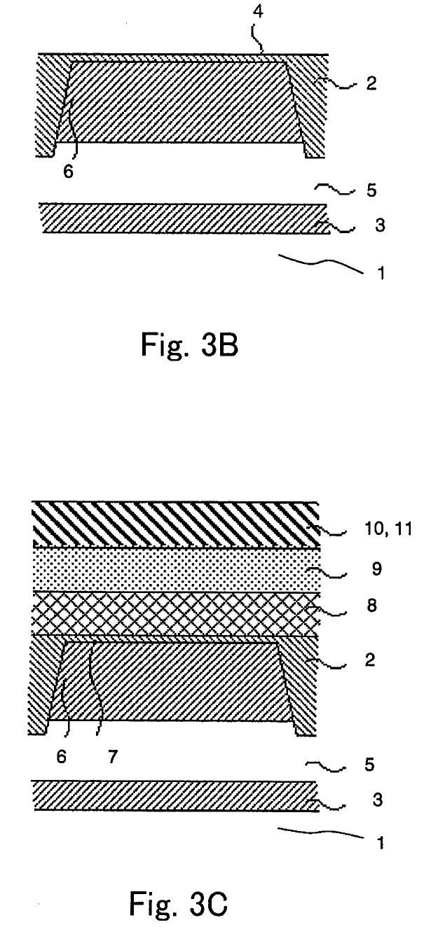

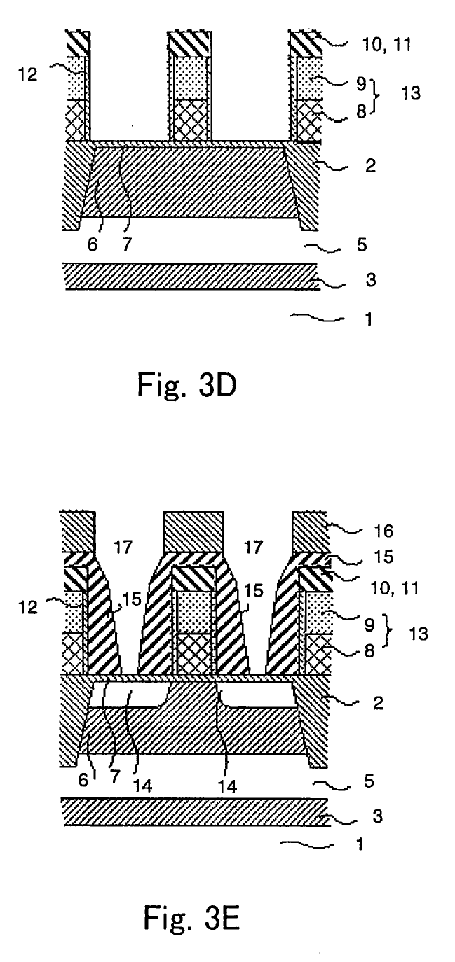

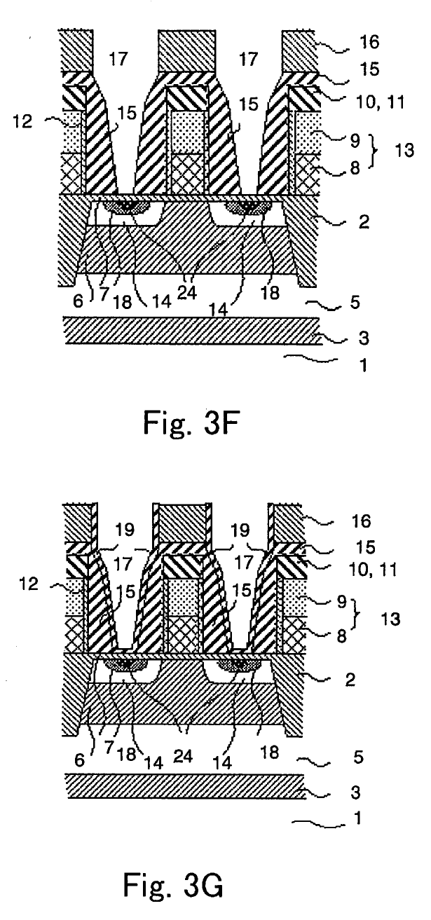

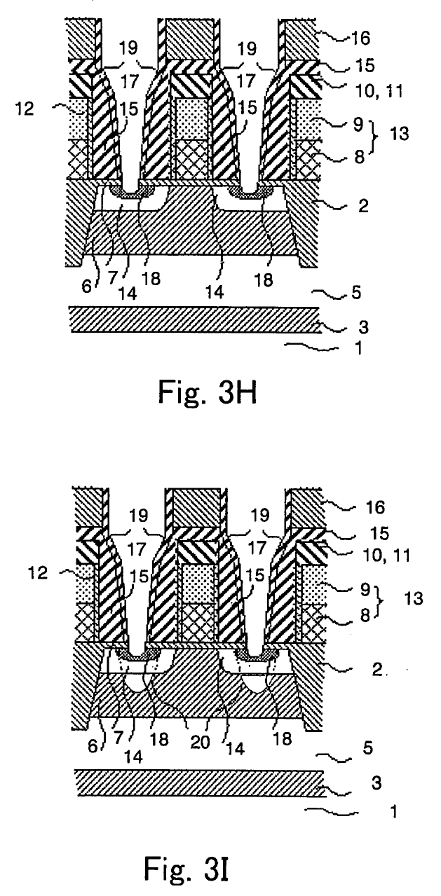

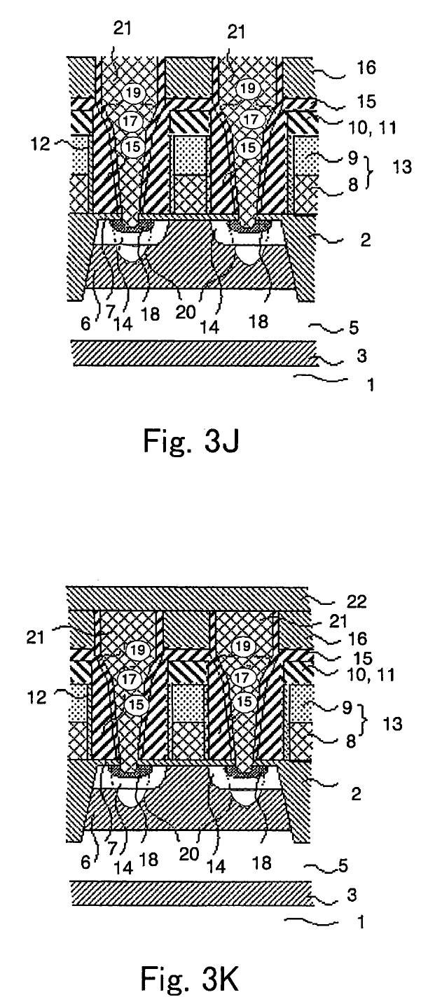

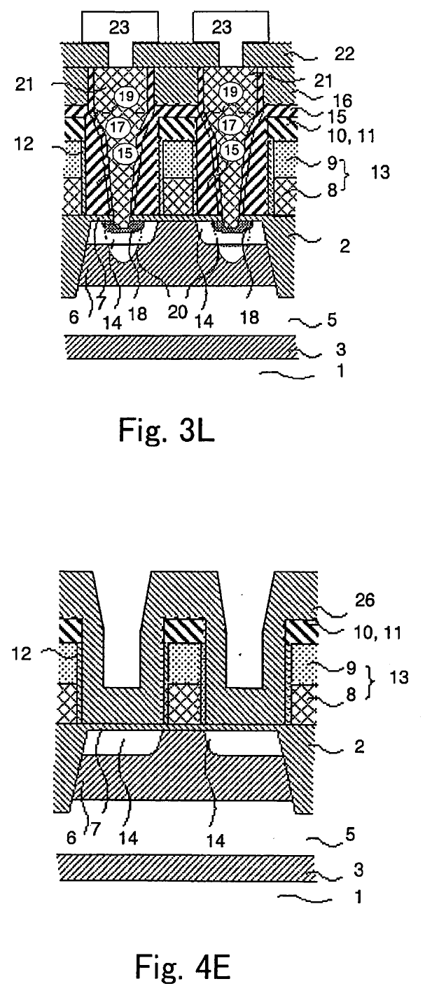

A first embodiment of the present invention will be described in detail with reference to the drawings. FIGS. 1A and 1B are cross-sectional views showing the vicinity of a drain according to a first embodiment and a related art, respectively. FIG. 2 is a diagram illustrating gate voltage dependency of drain current. FIGS. 3A to 3L are cross-sectional views showing primary steps according to the first embodiment of the present invention. FIG. 5 is a diagram illustrating correlation between refresh time and fraction defective.

Referring to these drawings, a manufacturing method according to the first embodiment will be described. To obtain a state shown in FIG. 3A, a groove is formed in a surface of a silicon substrate 1. The groove is filled with an insulation film 2 to separate elements and to isolate an active region. Subsequently, a 10-nm thick silicon oxide film 4 is formed on the surface of the substrate 1. Phosphorus ions are implanted through the silicon oxide film 4 with a dose of 1×10¹³/cm² at acceleration energy of 1500 keV to form an n-type buried well layer 3. Similarly, boron implantation is carried out with a dose of 1×10¹³/cm² at acceleration energy of 300 keV, and then with a dose of 4×10¹²/cm² at acceleration energy of 100keV to form a p-type well layer 5. Thus, the state of FIG. 3A is obtained.

Subsequently, boron implantation is performed with a dose of 1×10¹³/cm² at acceleration energy of 15 keV. Heat treatment is then performed in the nitrogen atmosphere at 1000° C. for 10 seconds to thereby form a p-type channel doped layer 6 as shown in FIG. 3B. After removal of the oxide film 4, a 7-nm thick gate oxide film 7 is formed on the silicon surface as shown in FIG. 3C. There are sequentially deposited on the gate oxide film 7, a 70-nm thick polycrystalline silicon film 8 containing high concentration of phosphorus, a 100-nm thick tungsten silicide film 9, a 25-nm thick silicon oxide film 10, and a 150-nm thick silicon nitride film 11 (in the drawings, the silicon oxide film 10 and the silicon nitride film 11 are indicated collectively as the film 10, 11).

Subsequently, as shown in FIG. 3D, the silicon nitride film 11, the silicon oxide film 10, the tungsten silicide film 9, and the polycrystalline silicon film 8 are patterned to form a gate electrode 13 composed of the polycrystalline silicon film 8 and the tungsten silicide film 9. Subsequently, a 10-nm thick gate sidewall oxide film 12 is formed on the side surface of the gate electrode 13 by a thermal oxidation method. Phosphorus implantation is then performed through the oxide film 7 with a dose of 1×10¹³/cm² and at acceleration energy of 20 keV, using the gate electrode 13 and the oxide film 12 as a mask. Heat treatment is performed in the nitrogen atmosphere at a temperature of 950° C. for 10 seconds to thereby form an n-type low-concentration diffusion layer 14 serving as a source/drain diffusion layer of the semiconductor device as shown in FIG. 3E.

Subsequently, a 40-nm thick silicon nitride film 15 and a 700-nm thick silicon oxide film 16 are sequentially deposited. The silicon oxide film 16 is planarized by a well-known method, and a contact hole 17 is formed by a self-aligned contact method. The etching for the contact hole 17 is stopped on the oxide film 7 by end-point detection. A part of the silicon nitride film 15 becomes a sidewall formed on the oxide film 12.

Subsequently, as shown in FIG. 3F, arsenic is implanted with a dose of 1×10¹3/cm² at acceleration energy of 25 keV in order to reduce the resistance of the n-type low-concentration layer by using the silicon nitride film 15 as a mask, and thus a resistance reduction arsenic layer 18 is formed. The arsenic ion implantation causes generation of a damaged region 24 containing many point defects and lattice distortions at a distance of several nanometers from the silicon interface, that is, in the vicinity of the projected range position of arsenic.

Subsequently, as shown in FIG. 3G, a 10-nm thick sidewall nitride film 19 is deposited on side surfaces of the silicon nitride film 15 and the silicon oxide film 16 by a well-known low pressure chemical vapor deposition (LPCVD) method. At the same time, the 10-nm thick nitride film is also similarly deposited on the bottom of the contact hole. The nitride film and the oxide film 7 on the bottom of the contact hole are etched away by using the sidewall nitride film 19 as a mask. The etching gas used for this purpose is consisting of CF₄, Ar, O₂ and CHF₃, while the selection ratio to silicon is kept high. Subsequently, as shown in FIG. 3H, plasma etching is performed with the use of etching gas consisting of O₂ and CF₄ to etch away the silicon layer to a depth of approximately 10 nm. The damaged region 24 extends to a distance of several nanometers from the silicon interface. Accordingly, most of the damaged region 24 can be effectively etched away while leaving the arsenic region directly below the sidewall nitride film 19. Thus, the sidewall nitride film 19 serves as the mask during the plasma etching. Subsequently, as shown in FIG. 3I, phosphorus is implanted with a dose of 1×10¹³/cm² at acceleration energy of 60 keV to form an electric field relaxation layer 20, using the sidewall nitride film 19 as a mask.

Subsequently, as shown in FIG. 3J, polycrystalline silicon containing a high concentration of phosphorus is deposited and etched back by a well-known method to thereby form a polycrystalline silicon plug 21. Subsequently, as shown in FIG. 3K, a 200-nm thick oxide film 22 is deposited, and heat treatment is performed in the nitrogen atmosphere at 980° C. for 10 seconds to thereby restore the defects due to the ion implantation. As shown in FIG. 3L, the oxide film 22 is then patterned to form a contact hole. Thereafter, a wiring material is deposited and patterned to form a wiring 23.

According to the first embodiment, the damaged region 24 containing many point defects and lattice distortions in the vicinity of the projected range position of the arsenic implanted in FIG. 3F is removed by the etching in FIG. 3H, and thus the remaining of the secondary defects is suppressed. The presence of the arsenic layer 18 under the sidewall nitride film 19 prevents the increase of the resistance that is caused by the arsenic layer directly below the contact hole being etched away and becoming thinner. FIG. 2 shows simulation values of dependency of drain current to gate voltage of semiconductor devices formed by the method according to the first embodiment and a related method. In FIG. 2, small squares of (a) and black circles of (b) are corresponding to the first embodiment and a related method, respectively. It can be seen that both the semiconductor devices have equivalent characteristics.

When the present invention is applied to a DRAM cell transistor, the probability of the implantation defect remaining as secondary defects can be reduced without deterioration of the cell transistor performance. FIG. 5 shows correlations between refresh time and number of defective bits observed when a 512 M-bit DRAM is used and “1” is written in all the bits. In FIG. 5, a solid line of (a) represents refresh time distribution according to the present invention and a broken line of (b) represents refresh time distribution according to a related method. The fraction defective is reduced in the lower part of the refresh time distribution (a) more than in the refresh time distribution (b).

FIGS. 1A and 1B are cross-sectional views mainly showing drain portions of n-type MOS semiconductor devices according the first embodiment of the present invention and a related method, respectively. According to the related method shown in FIG. 1B, arsenic implantation for reduction of the serial resistance of the semiconductor device is performed after a contact hole is formed by etching through to the silicon substrate. Therefore, the damages due to the arsenic implantation remain as secondary defects. As a result, the depletion layer 25 comes into contact with the secondary defects (or the damaged region 24), triggering generation of junction leak current. According to the first embodiment of the present invention shown in FIG. 1A, in contrast, the damaged region 24 significantly damaged by the arsenic implantation damage is removed, and thus the remaining of the secondary defects can be suppressed. Therefore, the junction leak current is also suppressed.

Further, the arsenic layer formed under the sidewall nitride film 19 prevents the increase of resistance that is caused by the arsenic layer directly under the contact hole being thinned by the etching. Accordingly, as shown in FIG. 2, the drain current is allowed to have equivalent characteristics to those obtained by the related method (indicated by the plot line (b)). When the present invention is applied to a DRAM cell transistor, the probability of the implantation defects remaining as secondary defects can be reduced without deterioration of the performance of the cell transistor. Therefore, as shown in FIG. 5, the fraction defective in the lower part of the refresh time distribution can be reduced.

According to the method for manufacturing a semiconductor device of the present invention, arsenic implantation for reduction of the serial resistance is performed after formation of a contact hole. A sidewall film is then formed on a side surface defining the contact hole. The silicon is etched away by using the sidewall film as a mask, so that the region around the projected range position of the arsenic containing many implantation damages is removed while leaving unetched the arsenic region directly below the sidewall film. The removal of the ion implantation damaged region 24 suppresses the remaining of the secondary defects, and thus is able to prevent generation of junction leak current caused by contact between the depletion layer and the secondary defects. When the present invention is applied to a DRAM cell transistor, a semiconductor device having desirable refresh characteristics can be manufactured.

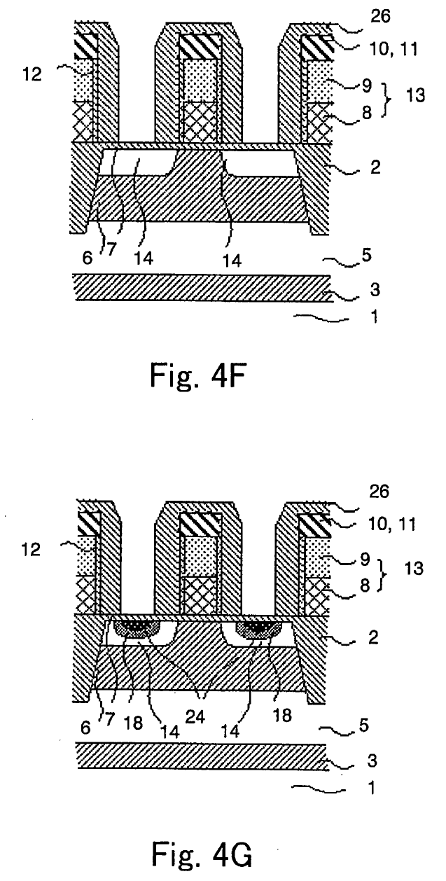

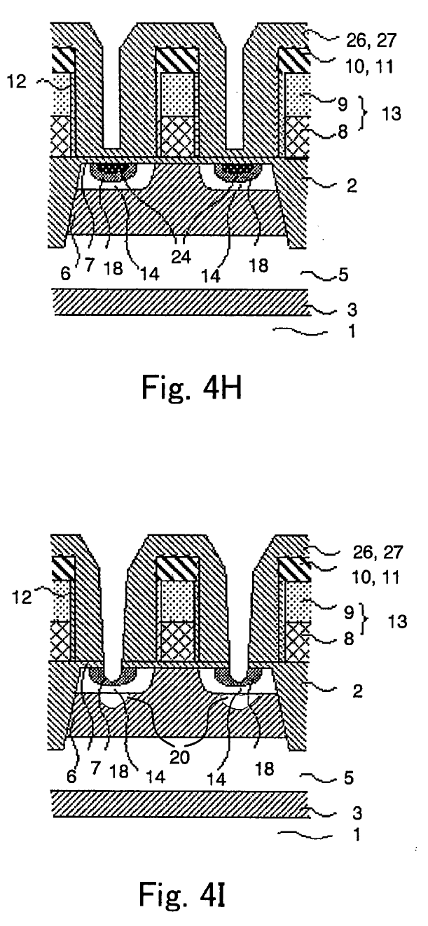

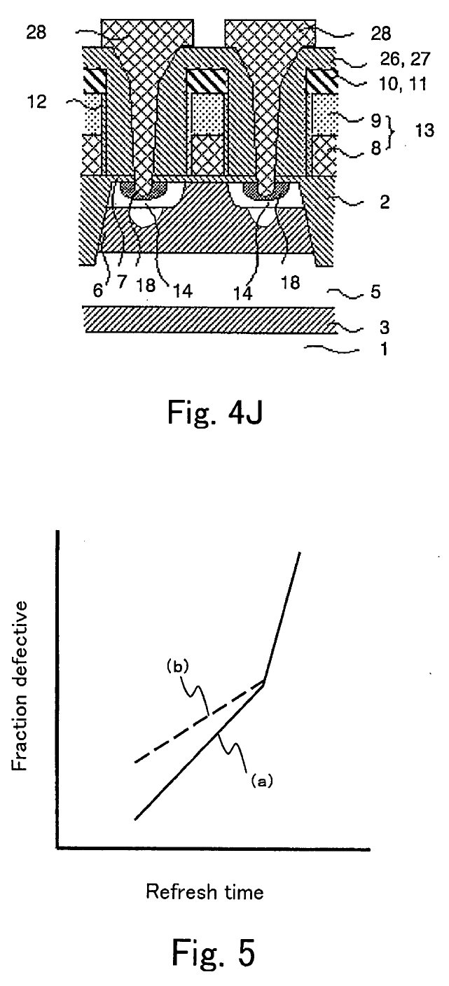

A second embodiment of the present invention will be described with reference to FIGS. 4E to 4J. The second embodiment is applied in a process using polycrystalline silicon pads. Same manufacturing steps as those in the first embodiment are conducted up to the formation of a gate electrode as shown in FIGS. 3A to 3D. FIGS. 4E to 4J are cross-sectional views showing subsequent primary steps.

In a manufacturing method according to the second embodiment, same manufacturing steps as those in the first embodiment are conducted up to the formation of a gate electrode as shown in FIGS. 3A to 3D. Subsequently, phosphorus implantation is performed through the gate oxide film 7 with a dose of 1×10¹³/cm² at acceleration energy of 20 keV, by using the gate electrode 13 and the gate sidewall oxide film 12 as a mask. Heat treatment is then performed in the nitrogen atmosphere at a temperature of 950° C. for 10 seconds to thereby form an n-type low concentration diffusion layer 14 which defines a source/drain diffusion layer of a semiconductor device as shown in FIG. 4E.

Subsequently, a 30-nm thick silicon oxide film 26 is deposited. The silicon oxide film 26 is then etched, as shown in FIG. 4F, by a well-known etch-back method. A part of the silicon oxide film 26 becomes a sidewall formed on the side oxide film 12. Subsequently, as shown in FIG. 4G, arsenic is implanted with a dose of 1×10¹³/cm² at acceleration energy of 20 keV to form a resistance reduction arsenic layer 18 by using the silicon oxide film 26 as a mask for the purpose of reducing the resistance of the n-type low concentration layer. This ion implantation causes production of a damaged region 24 containing many point defects and lattice distortions, in the vicinity of the projected range position of arsenic.

Subsequently, as shown in FIG. 4H, a silicon oxide film 27 of a same type as the silicon oxide film 26 is deposited to a thickness of 10 nm (the silicon oxide films 26 and 27 are collectively represented in the diagram). As shown in FIG. 41, the oxide films 27 and 7 on the active region are etched away by using the oxide films 26 and 27 deposited on the side surface of the side oxide film 12 as a mask. The silicon layer is further etched to a depth of approximately 10 nm by using the mask of the oxide films 26 and 27. As a result, the damaged region 24 is etched away while leaving the arsenic region directly below the sidewall film (or the oxide films 26, 27). Phosphorus is further implanted with a dose of 1×10¹³/cm² at acceleration energy of 60 keV to form an electric field relaxation layer 20 by using the oxide films 26, 27 as a mask. Subsequently, as shown in FIG. 4J, polycrystalline silicon containing a high concentration of phosphorus is deposited and patterned to form a polycrystalline silicon pad 28.

In the method of manufacturing for a semiconductor device according to the second embodiment, arsenic implantation is performed to reduce the series resistance after formation of the contact hole, and thereafter a sidewall film is formed on the side surface defining the contact hole. The silicon is etched away by using the sidewall film as a mask, whereby the region around the projected range position of arsenic and containing many implantation damages is removed while leaving the arsenic region directly below the sidewall film. The removal of the damaged region 24 damaged by the ion implantation suppresses the remaining of secondary defects, and thus the generation of junction leak current caused by the contact between the depletion layer and the secondary defects can be prevented. When applying the second embodiment to a DRAM cell transistor, a semiconductor device having desirable refresh characteristics can be produced in a similar manner to the first embodiment.

Although the present invention has been described based on its preferred embodiments with a certain degree of particularity, it is to be understood that the present invention is not limited to these embodiments but may be otherwise variously embodied within the scope and sprit of the invention. These modifications and variations should be considered to be within the scope of the invention. For example, heat treatment may be applied after formation of the resistance reduction arsenic layer 18 in order to restore the implantation defects. The heat treatment may be high-temperature and short-time heat treatment performed for example at a temperature of 1000° C. for 10 seconds, or low-temperature and long-time heat treatment performed for example at a temperature of 600° C. for one hour, or combination thereof. Such heat treatment is also able to effectively restore the defects while suppressing the impurity redistribution. The heat treatment may be performed not only in an inert atmosphere but also in an oxidizing atmosphere to further enhance the effect of restoration of the defects. Since there exists the gate oxide film 7 in the bottom of the contact hole 17, the growth of additional oxide film caused by the oxidizing atmosphere in the bottom of the contact hole 17 will be insignificant as long as the heat capacity is in such a range as to suppress the impurity redistribution. Thus, the additional oxide film can be etched together during etching of the gate oxide film 7. As a result, the number of the manufacturing steps is not increased.

What is claimed is:

1. A method for manufacturing a semiconductor device comprising:
an ion implantation step of performing ion implantation to form a resistance reduction diffusion layer; and
an etching step of etching away a damaged region of the resistance reduction diffusion layer formed by the ion implantation.

2. The method for manufacturing a semiconductor device according to claim 1, wherein a sidewall film is formed after the ion implantation step, and the damaged region of the resistance reduction diffusion layer formed by the ion implantation is etched away by using the sidewall film as a mask.

3. The method for manufacturing a semiconductor device according to claim 2, wherein an electric field relaxation diffusion layer is further formed by using the mask after the etching step.

4. The method for manufacturing a semiconductor device according to claim 2, wherein the sidewall film comprises a nitride film.

5. The method for manufacturing a semiconductor device according to claim 2, wherein the sidewall film comprises a silicon oxide film.

6. The method for manufacturing a semiconductor device according to claim 2, wherein the damaged region is removed by being etched away to a depth of approximately 10 nm by the etching step.

7. The method for manufacturing a semiconductor device according to claim 2, wherein the resistance reduction diffusion layer is formed by implantation of arsenic ions.

8. A method for manufacturing a semiconductor device comprising the steps of:
forming a side oxide film;
forming a low concentration diffusion layer by using the side oxide film as a first mask;
forming a first sidewall film on the side oxide film;
forming a resistance reduction diffusion layer by using the first sidewall as a second mask;
forming a second sidewall film on the first sidewall;
etching away a damaged region of the resistance reduction diffusion layer by using the second sidewall as a third mask; and
forming an electric field relaxation diffusion layer by using the third mask.

9. A semiconductor device comprising:
a resistance reduction diffusion layer formed by ion implantation, wherein a damaged region of the resistance reduction diffusion layer formed by the ion plantation is etched away.

10. The semiconductor device according to claim 9, wherein the semiconductor device is a dynamic random access memory.
